(19) United States
(12) Patent Application Publication
(10) Pub. No.: US 2009/0153266 A1
(43) Pub. Date: Jun. 18, 2009

(54) Modulized wave filter

(76) Inventor: Cheng-I Lin, Beimen Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/000,344

(22) Filed: Dec. 12, 2007

(51) Int. Cl. H03H 7/00

(52) U.S. Cl. 333/167

(57) ABSTRACT

A wave filter includes a circuit board, and a shell housing the circuit board; the circuit board includes a band-pass wave-filtering circuit, and a low-pass wave-filtering circuit; the shell has an input end and an output terminal thereon, which are connected to the band-pass wave-filtering circuit of the circuit board; the shell further has an output end thereon, which is connected to the low-pass wave-filtering circuit; thus, the wave filter is modulized; the wave filter is fitted in a multimedia wideband router, and in turn it is not necessary to change wave filters in order for allowing the multimedia wideband router to be connected to and used with televisions or various digital multimedia equipments.

### BACKGROUND OF THE INVENTION

1. Field of the Invention

The present invention relates to a wave filer, more particularly one, which is modulized, and fitted in a multimedia wideband router so that it is not necessary to change wave filters on the multimedia wideband router for allowing the wideband router to be connected to and used with televisions or various digital multimedia equipments.

2. Brief Description of the Prior Art

It is a development trend of home networking to combine various digital devices with computers and digital multimedia equipments. Wireless Local Area Network (WLAN for short), UWB, HomePlug, and the Multimedia over Coax Alliance (MoCA) are among the currently existing techniques of home networking. The Multimedia over Coax Alliance was established by its founding members in January 2004, and develops specifications for home networking over in-home co-axial cable. The goal of the Multimedia over Coax Alliance is to facilitate home networking on existing coaxial cable, which can be used for data connections to telephones, network, set top boxes, cable TV (CATV), Satellite Master Antenna Television System (SMATV), Wireless Local Area Network (WLAN) and other entertainment devices without the need for new connections.

However, the following problems will arise when the MoCA networking technique is used; a multimedia wideband router for the above purpose has to be connected to various wave filters with different wave-filtering effects, which are used to filter various signals sent through the coaxial cable in order to obtain signals of needed frequency bands as well as signals of the frequency band between 975 MHz and 1525 MHz stipulated by Multimedia over Coax Alliance (MoCA). Therefore, it is necessary to change wave filters on the multimedia wideband router in order for allowing the multimedia wideband router to be connected to and used with televisions/various digital multimedia equipments, causing a lot of inconvenience.

Therefore, it t is a main object of the present invention to provide a modulized wave filter to overcome the above problems.

### SUMMARY OF THE INVENTION

A modulized wave filter according to an embodiment of the present invention includes a circuit board, and a shell housing the circuit board; the circuit board includes a band-pass wave-filtering circuit, and a low-pass wave-filtering circuit; the shell has an input end and an output terminal thereon, which are connected to the band-pass wave-filtering circuit; the shell further has an output end thereon, which is connected to the low-pass wave-filtering circuit. A modulized wave filter according to another embodiment of the invention includes a circuit board, which includes a high-pass wave-filtering circuit, and a low-pass wave-filtering circuit; the shell has an input end and an output terminal, which are connected to the high-pass wave-filtering circuit; the shell further has an output end, which is connected to the low-pass wave-filtering circuit. The modulized wave filter is fitted in a multimedia wideband router, and in turn it is not necessary to change wave filters in order for allowing the multimedia wideband router to be connected to and used with televisions or various digital multimedia equipments. Therefore, the manufacturing cost of multimedia wideband routers can reduce to a large extent, and it will take much less time in assembly.

### BRIEF DESCRIPTION OF THE DRAWINGS

The present invention will be better understood by referring to the accompanying drawings, wherein:

FIG. 1 is a structural view of the present invention,

FIG. 2 is a front view of the present invention,

FIG. 3 is a structural view of a second preferred embodiment of the present invention,

FIG. 4 is a structural view of a third preferred embodiment,

FIG. 5 is a front view of the second and the third preferred embodiments, and

FIG. 6 is a front view of a modulized wave filter of the present invention with partitioning plates.

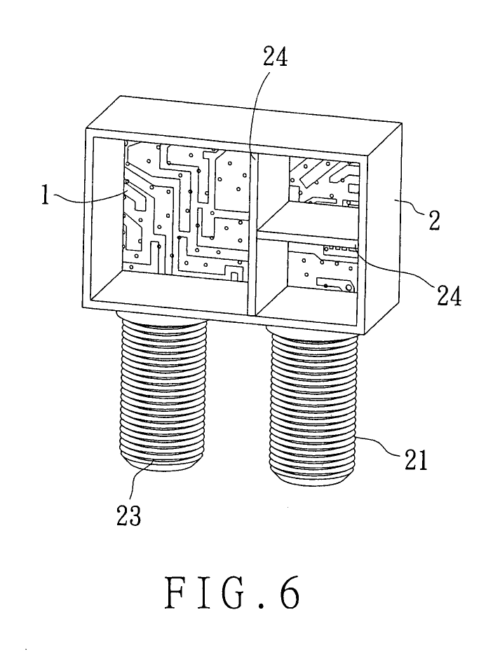

### DETAILED DESCRIPTION OF THE PREFERRED EMBODIMENTS

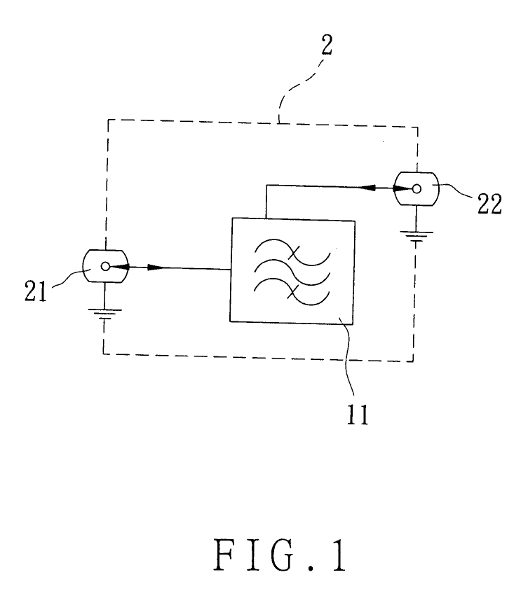

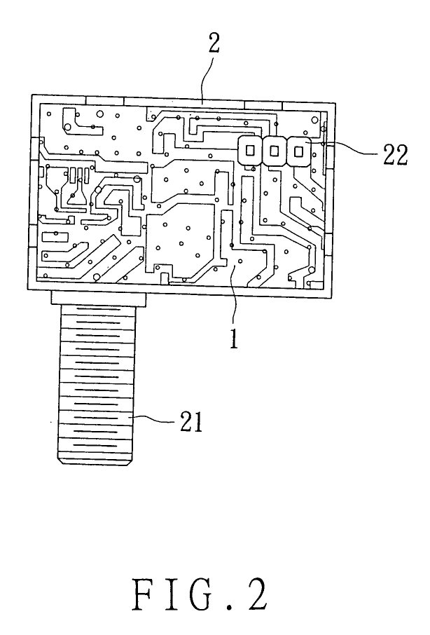

Referring to FIGS. 1 and 2, a first preferred embodiment of a modulized wave filter of the present invention includes a circuit board 1, and a shell 2 housing the circuit board 1. The circuit board 1 includes a band-pass wave-filtering circuit 11. And, the shell 2 has an input end 21 and an output terminal 22 thereon, and the band-pass wave-filtering circuit 11 of the circuit board 1 is connected to both the input end 21 and the output terminal 22; thus, the wave filter is modulized.

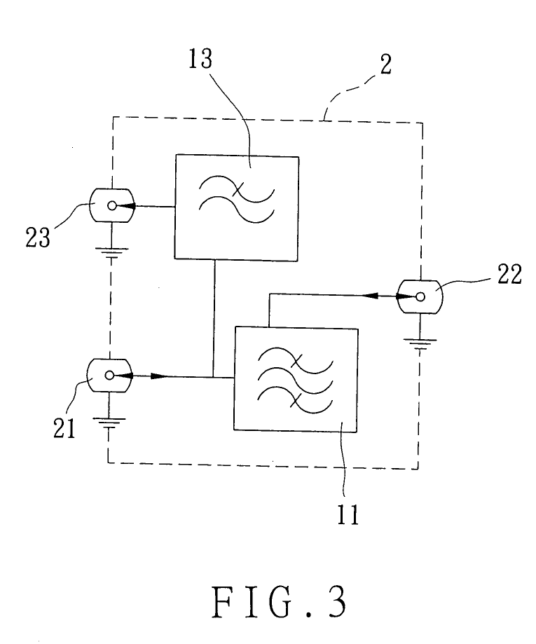

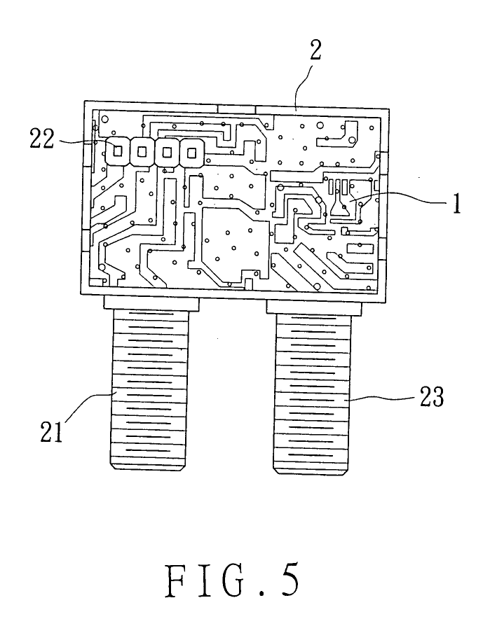

Referring to FIG. 3, a second preferred embodiment of a modulized wave filter of the present invention includes a circuit board 1, and a shell 2 housing the circuit board 1. The circuit board 1 includes a band-pass wave-filtering circuit 11, and a low-pass wave-filtering circuit 13. The shell 2 has an input end 21 and an output terminal 22 thereon, which are connected to the band-pass wave-filtering circuit 11 of the circuit board 1. The shell 2 further has an output end 23 thereon, and the output end 23 is connected to the low-pass wave-filtering circuit 13 of the circuit board 1. Therefore, the wave filter is modulized, as shown in FIG. 5.

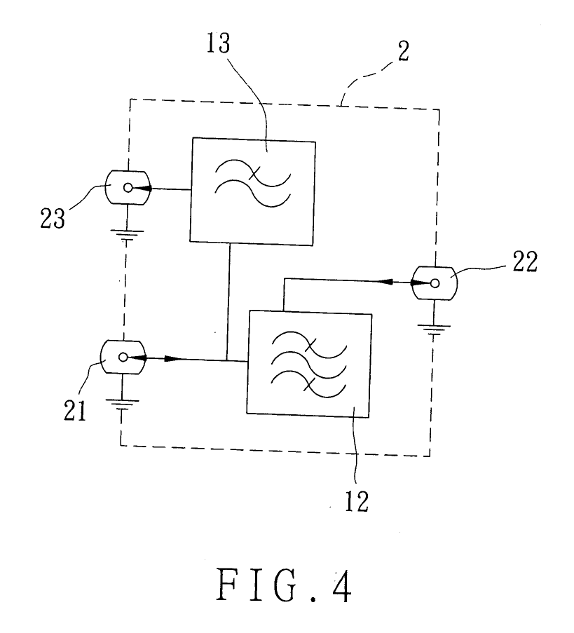

Referring to FIG. 4, a third preferred embodiment of a modulized wave filter of the present invention includes a circuit board 1, and a shell 2 housing the circuit board 1. The circuit board 1 includes a high-pass wave-filtering circuit 12, and a low-pass wave-filtering circuit 13. The shell 2 has an input end 21 and an output terminal 22 thereon, and the high-pass wave-filtering circuit 12 of the circuit board 1 is connected to both the input end 21 and the output terminal 22. The shell 2 further has an output end 23 thereon, and the low-pass wave-filtering circuit 13 of the circuit board 1 is connected to the output end 23. Therefore, the wave filter is modulized, as shown in FIG. 5.

Furthermore, the shell 2 has several partitioning plates 24 sticking from an inner side thereof to intervene between the wave-filtering circuits 11; 12, and 13 of the circuit board 1 so that glitches are isolated to prevent interference between the wave-filtering circuits.

The modulized wave filter of the present invention is fitted in a multimedia wideband router, with the input end 21 thereof being connected to a coaxial cable, and the output terminal 22 being connected to other circuits in the multimedia wideband router; the modulized wave filter further can be connected to a television at an output end 23 thereof. Therefore, it is not necessary to change wave filters in order for allowing the multimedia wideband router to be connected to and used with televisions or various digital multimedia equipments according to the standard of use stipulated by Multimedia over Coax Alliance (MoCA).

From the above description, it can be seen that the wave filter of the present invention has the following advantages over the prior art: band-pass wave-filtering circuits/high-pass wave-filtering circuits and low-pass wave-filtering circuits are combined in a shell so as to modulize the present wave filter. Therefore, the manufacturing cost of multimedia wideband routers can reduce to a large extent, and it will take less time in assembly; the modulized wave filter is fitted in a multimedia wideband router, and connected to the coaxial cables and televisions/other circuits in the multimedia wideband router, and in turn it is not necessary to change wave filters in order for allowing the multimedia wideband router to be connected to and used with televisions or various digital multimedia equipments. In summary, the present invention is very practical and economical to use.

What is claimed is:

1. A modulized wave filter, comprising
a circuit board, the circuit board including a band-pass wave-filtering circuit; and
a shell housing the circuit board;
the shell having an input end thereon, which is connected to the band-pass wave-filtering circuit; the shell having an output terminal thereon, which is connected to the band-pass wave-filtering circuit; the shell housing a plurality of partitioning plates, which are next to the band-pass wave-filtering circuit.

2. A modulized wave filter, comprising
a circuit board, the circuit board including a band-pass wave-filtering circuit, and a low-pass wave-filtering circuit; and
a shell housing the circuit board;
the shell having an input end and an output terminal thereon, which are connected to the band-pass wave-filtering circuit of the circuit board; the shell having an output end thereon, which is connected to the low-pass wave-filtering circuit of the circuit board; the shell housing a plurality of partitioning plates, which are next to the wave-filtering circuits of the circuit board.

3. A modulized wave filter, comprising
a circuit board, the circuit board including a high-pass wave-filtering circuit, and a low-pass wave-filtering circuit; and
a shell housing the circuit board;
the shell having an input end and an output terminal thereon, which are connected to the high-pass wave-filtering circuit of the circuit board; the shell having an output end thereon, which is connected to the low-pass wave-filtering circuit of the circuit board; the shell housing a plurality of partitioning plates, which are next to the wave-filtering circuits of the circuit board.
